(19) United States
(12) Patent Application Publication
(10) Pub. No.: US 2010/0026387 A1
(43) Pub. Date: Feb. 4, 2010

(54) INTEGRATED DOHERTY TYPE AMPLIFIER ARRANGEMENT WITH HIGH POWER EFFICIENCY

(75) Inventor: Igor Blednov, Nijmegen (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/515,645

(22) PCT Filed: Nov. 21, 2007
(86) PCT No.: PCT/IB07/54732

§ 371 Date: May 20, 2009

(30) Foreign Application Priority Data
Nov. 23, 2006 (EP) 06024273.2

(51) Int. Cl. H03F 3/68

(52) U.S. Cl. 330/124 R

(57) ABSTRACT

The present invention shows a Doherty type of amplifier arrangement comprising a plurality of parallel unit cells. Each unit cell is of relatively low power. Suitably it comprises a compensation circuit at the input of the main amplifier and peak amplifier stage.

The present invention relates to an integrated Doherty type amplifier arrangement and a method of amplifying an input signal of such a Doherty type amplifier arrangement.

In recent years, there has been a strong demand to improve the efficiency of power amplifiers for wireless communications. The use of the Doherty technique allows to maintain the efficiency of the power amplifier across a wide range of input power variation. The Doherty amplifier was first suggested by W. H. Doherty in 1936 and is discussed in a technical paper and titled “A New High Efficiency Power Amplifier For Modulated Waves”, W. H. Doherty, Proceedings of the Institute of Radio Engineers, Vol. 24, No. 9, September 1936. Originally intended for use in low to medium frequency amplitude modulated broadcasting transmitters, the suggested scheme can be modified and updated to increase efficiency of high frequency power amplifiers.

In a conventional amplifier there is a direct relationship between efficiency and input drive level. Therefore, high efficiency is not attained until the high frequency input power becomes sufficiently high to drive the amplifier into saturation. Since in multi-carrier communications systems an amplifier must remain as linear as possible in order to avoid intermodulation distortion, this region of high efficiency cannot be used.

The Doherty amplifier schema achieves high linear efficiency by having a first amplifier (main amplifier or carrier amplifier) operated at a point where the output begins to saturate and where the highest linear efficiency is obtained. Additionally, a second amplifier (peak amplifier or auxiliary amplifier) is used to affect the first so that overall linearity can be maintained as it is driven beyond this saturation point. The Doherty amplifier's operation can thus be divided into two main regions. In the first region, the input power is less than the peak amplifier's threshold and only the carrier amplifier supplies the output power to the load with the efficiency determined by its mode of operation, i.e. AB-class, B-class, F-class or E-class, which defines the location of the bias working point of the amplifier. As the input drive voltage or power increases further to a level just before the carrier amplifier becomes saturated, i.e. the point where the peak efficiency is obtained, the peak amplifier starts to operate and this mark is the beginning of the second region. Through the connection of a quarter-wave transformer, the power supplied by the peak amplifier effectively reduces the output load impedance seen by the carrier amplifier. This impedance reduction enables the carrier amplifier to deliver more power to the load while its voltage remains saturated. In this way, the maximum efficiency of the carrier amplifier and hence the overall Doherty amplifier is maintained throughout the region until the peak amplifier reaches its saturation. However, variable input impedances of the power devices especially when used in C-class operating mode (with bias providing conducting angle less that 180 degrees), which is often the case for the peak amplifier, lead to amplitude and phase distortions depending on the power level, which its extremely detrimental for code multiplex system, such as Wideband Code Division Multiple Access (WCDMA) communication systems. Furthermore, the variable input impedances lead to power reflections from the input of the power devices operating in the peak and main amplifiers and this results in an undesirable mutual influence or coupling effect.

On one hand, the Doherty technique requires use of similar devices in the carrier (or main) and peak amplifiers to provide best linearity, but, on the other hand, both power devices are operating in different modes, e.g. the main amplifier in AB-class and the peak amplifier in C-class, which cause large differences in power gain. Thus, the Doherty amplifier's characteristic comprises a power range where the gain starts to decrease and thus introduces increased output amplitude modulations based on input amplitude modulations (i.e. AM-AM distortions) due to the fact that the peak amplifier operating in C-class has a lower gain and the load impedance at the main amplifier output drops due to the Doherty principal.

Another bottleneck of the Doherty amplifier results from required 90° lines at the input and output of the Doherty amplifier, which cause a limited frequency band of operation.

In view of the above drawbacks, improvements of the Doherty performance are required to achieve an electrical isolation between the input ports of the peak and main amplifiers and between the common Doherty input and the respective inputs of the peak and main amplifiers. Furthermore, a wideband 90° phase difference between the two signals applied to the main and peak amplifier inputs is desirable.

Moreover, as the Doherty amplifier technique is specifically addressed to wideband cellular communications systems, an integrated solution (MMIC) which can be used as mobile phone output amplifier and which can withstand severe impedance mismatches at the output side (voltage standing wave ratios (VSWR) of 1:10, for example) is desirable.

In the article “Lumped Element Based Doherty Power Amplifier Topology CMOS Process”, C. Tongchoi et al, IEEE, 2003, pp I-445 to I-448, a CMOS (Complementary Metal Oxide Semiconductors) microwave Doherty power amplifier is described, which maintains high power-added efficiency over a wide range of output power. The implementation is based on a combination of AB-class and C-class CMOS power amplifiers where the quarter-wave transformers are realized using lumped-element LC equivalents for high efficiency and compact design. Moreover, to minimize the inherently high substrate loss and further increase the level of integration, a quadrature 3-dB hybrid circuit, which splits the input signal equally but 90° different in phase to the main and peak amplifiers, is also substituted by its lumped equivalents. In particular, the quarter-wave transformer and the branch-line coupler are represented by π-type lumped-element equivalent circuits consisting of series inductors and parallel capacitors, which provides the advantage that inevitable parasitic capacitances associated with the bonding pads and the package can be absorbed into the parallel capacitors. The capacitors are suggested to be of a square type Metal-Insulator-Metal (MIM) structure, while all inductors are suggested to be integrated planar spiral inductors.

However, the above document does not address the above problems and do not provide a industrially viable solution that provides sufficient power in sufficient bandwidth with sufficient efficiency. The performance of Doherty amplifier arrangements has turned out to be extremely sensitive on assembly. It requires the tuning of each amplifier arrangement due to process spread. This tuning is a very expensive procedure, that a user of the Doherty amplifier arrangement would like to get rid off.

It is therefore an object of the invention to provide an improved Doherty amplifier arrangement.

This object its achieved by an integrated Doherty type amplifier arrangement as claimed in claim 1.

It has been the insight behind the invention that said problems can be solved by using a plurality of unit cells in parallel, each of the unit cells comprising a amplifier arrangement with the Doherty configuration. This was based on the further insight that the tuning problems of existing Doherty arrangement are due to the fact that a high power Doherty arrangement needs an output with a plurality of wirebonds. This use of a plurality of wirebonds is disclosed in itself in the patent application WO-A 2006/003608. However, the problem with conventional designs is that these wirebonds turn out to have a different inductance, due to different length or different interaction with their environment. That difference in inductance is problematic for good matching. Now by dividing a high power Doherty arrangement into a plurality of unit cells, each of the unit cells will have a lower power. This has two important effects: first, less wirebonds are needed per unit cell, so that the difference in inductance of the wirebonds will decrease, and thus the matching will improve. Secondly, the transistors constituting the main amplifier stage and the at least one peak amplifier stage are located at a smaller pitch, e.g. the distance between the centers of said stages reduces, since the amplifier can be smaller. And this results in a smaller process spread of the transistors during manufacture, and hence a more uniform amplification.

In a suitable embodiment, the unit cell is provided with a compensation circuit at the input terminal of the main amplifier stage. Such compensation circuit is most suitably a simple LC circuit that is connected to ground. However, it is not principally excluded that a more complex circuit is used, such as for instance a filter with pi or T-type topology. It is highly appreciated if both the main amplifier stage and the peak amplifier stage have such compensation circuit. This prevents that undesired effects take place when combining the first and second amplified signals.

In an advantageous embodiment, the inductor of the compensation circuit, to which will also be referred as compensation inductor, is defined in a metallisation layer of a carrier. It was found a suitable optimization of the amplifier arrangement that said compensation inductor is defined as an integrated inductor, whereas the inductors needed in the input and output circuits are implemented with wirebonds. Such inductors are particularly needed to generate the phase shift needed.

In an advantageous embodiment, the power level of a single unit cell is in the range of 1 to 20 W. The maximum of this range is defined by the acceptable level of bond wires to prevent any substantial difference in inductance between the bondwires. Experiments have shown that at a power level of 10 W a single wirebond is sufficient. This evidently is optimal.

The main amplifier stage and the peak amplifier stage of the amplifier arrangement do not need to be equal. As known, such amplifier stage comprises a transistor, which is most suitably a field effect transistor and can be made in a technology such as LDMOS, GaN and SiC. Specific arrangements of such transistors are known to the skilled person. One suitable transistor is disclosed in WO-A 2005/22645. It is most adequate to further include an ESD protection such as described in the non-prepublished application IB2006/053719 (Applicant's docket nr PH001494). These applications are herein included by reference. As is further known, the main amplifier stage is preferably operated as an A- or AB-class amplifier, whereas the peak amplifier stage is preferably operated as a C-class amplifier. However, this operation may be changed in connection with the power levels needed, with the bandwidth needed, with the center frequency of the frequency band for which the amplifier is designed. Suitably, the main amplifier stage is smaller than the peak amplifier stage. The term ‘smaller’ refers herein both the physical size and to power level.

These and other aspects of the invention will be elucidated with reference to the Figures, in which:

the present invention will now be described based on a preferred embodiment with reference to the accompanying drawings, in which:

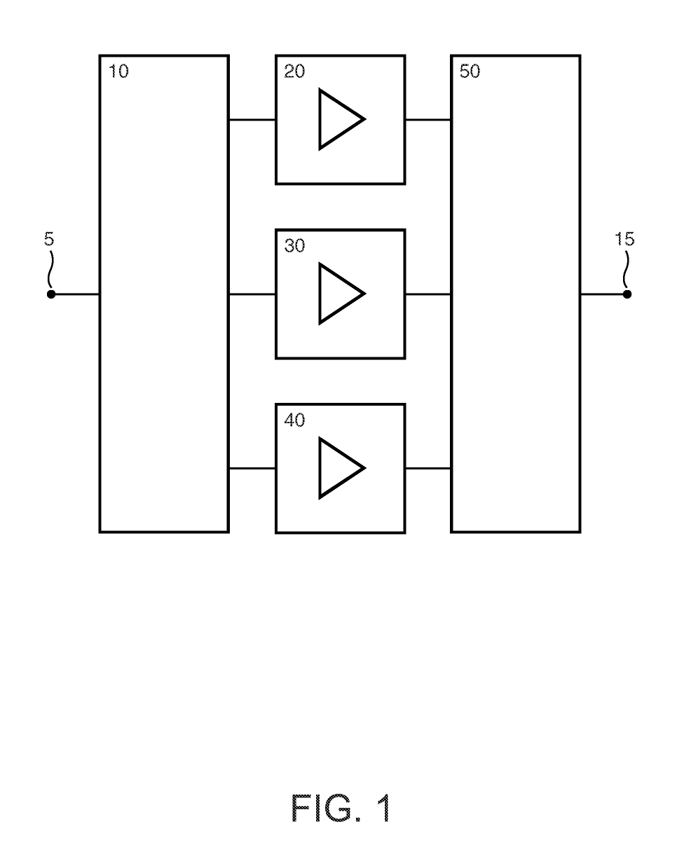

FIG. 1 shows a schematic block diagram of a Doherty type amplifier arrangement according to the preferred embodiment;

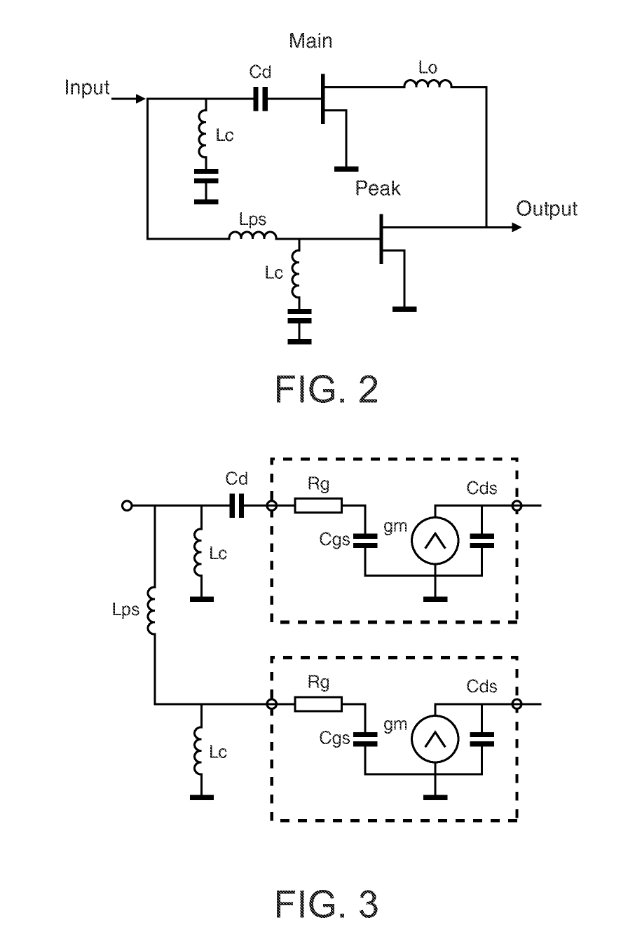

FIG. 2 depicts an embodiment of a Doherty amplifier, according to an embodiment of the invention;

FIG. 3 depicts a model of a Doherty amplifier according to an embodiment of the invention;

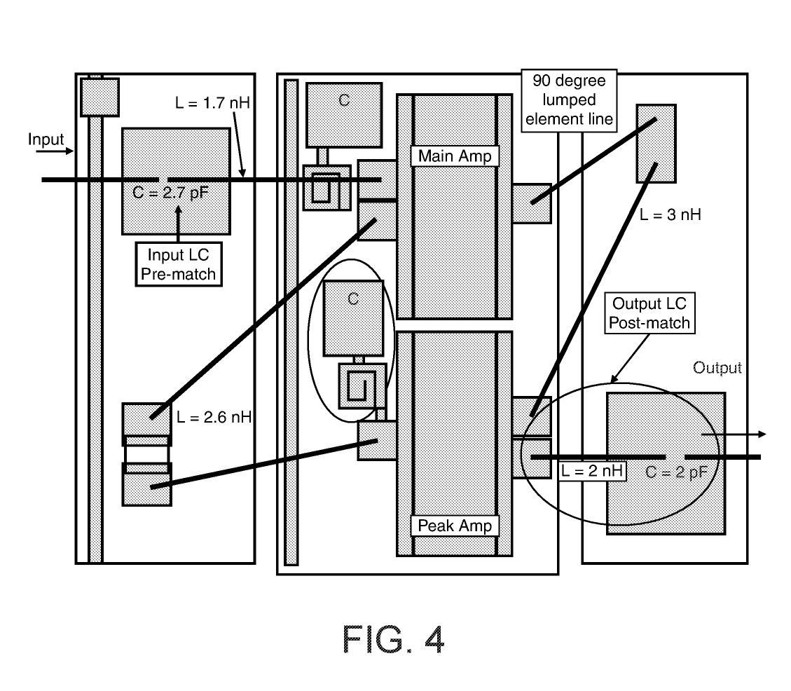

FIG. 4 shows a design example of a 10 W Doherty unit cell;

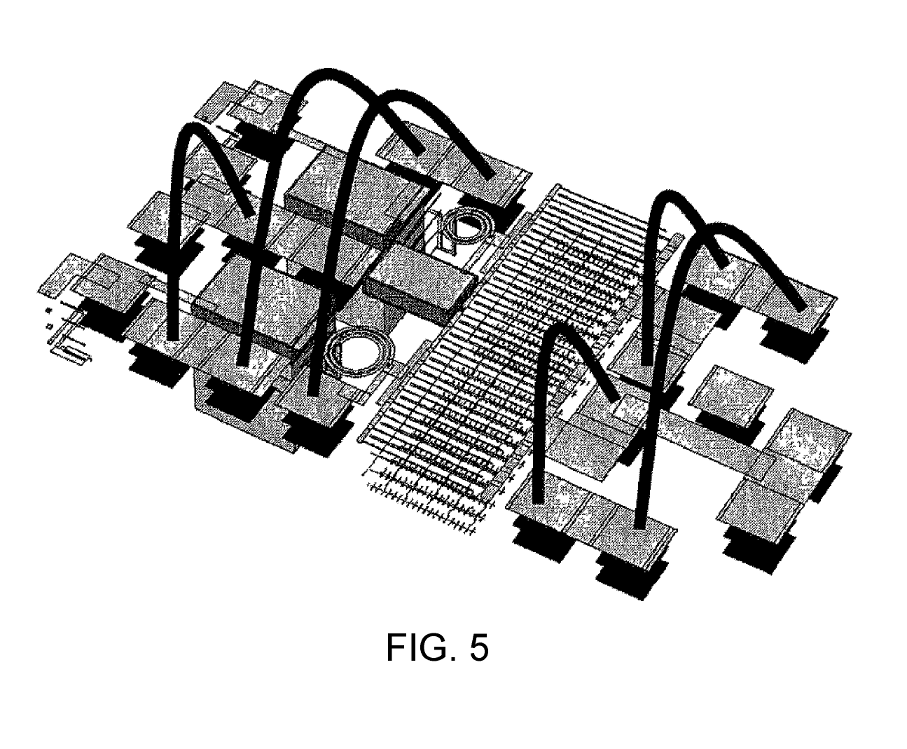

FIG. 5 shows a drawing in bird eye's perspective of a single unit cell, and

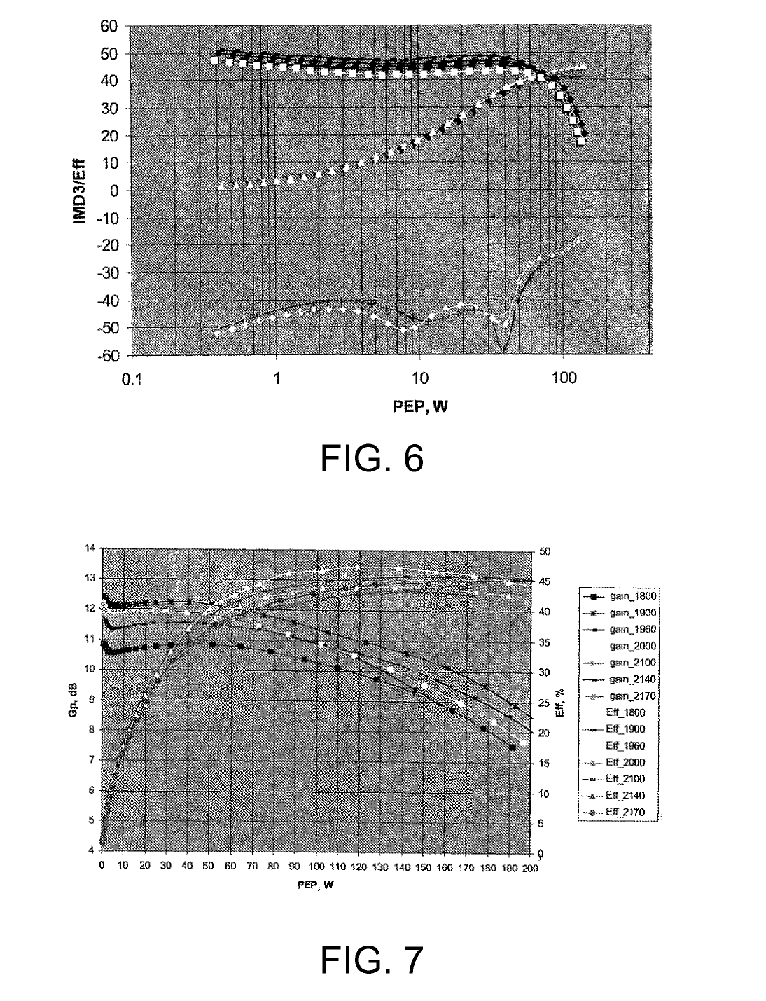

FIGS. 6 and 7 show a graph of the properties of the amplifier according to the invention.

The preferred embodiment will now be described in connection with an MMIC (Monolithic Microwave Integrated Circuit) Technology, which may be used in a transceiver design of a wireless system or any other radio frequency (RF) system. The application of MMIC technology has enabled miniaturization of microwave and millimeter-wave systems, combined with increasing performance.

In mobile RF transceivers of emerging wireless systems such as WCDMA, CDMA2000 or Wireless Local Area Network (WLAN) systems according to the IEEE 802.11 (a)/(g) standard, power amplifiers are used in transmitter stages, where the modulated RF signal is amplified before being supplied to the antenna for wireless transmission. These power amplifiers are the most power consuming part of these RF transceivers. Using a Doherty type amplifier arrangement, a highly efficient power amplifier can be provided.

In the power amplifier arrangement according to the preferred embodiment a Doherty structure is used, where circuit size is reduced for integration by using lumped elements to replace distributed circuit like power splitters and transmission lines. Furthermore, inductive coupling is used to increase inductance values and output parasitic capacitances are used as a part of lumped element artificial lines. Moreover, to avoid power losses in lumped elements and provide stable characteristic impedance in a wide frequency band including 2fo . . . nfo harmonics of fundamental signal, bond wires are suggested to be used as inductances. Bondwires provide very high parasitic parallel resonance frequency, e.g. above 15 GHz, as lumped inductance suitable for building a wideband lumped element equivalent of an RF transmission line.

FIG. 1 shows a schematic block diagram of Doherty type amplifier arrangement according to the invention. Very schematically, the figure shows an input 5, with an input pad 10, three parallel unit cells 20, 30, 40, an output pad 50 and an output 15.

FIG. 2 depicts an embodiment of unit cell of the a Doherty amplifier, according to an embodiment of the invention. An input signal received at an input terminal is supplied to an input circuit. This input circuit may include lumped element hybrid power dividers for splitting the input signal to a carrier or main amplifier and at least one peak amplifier. Suitably, two peak amplifiers are used to support the operation of the main amplifier. The output signals of the main amplifier and the peak amplifier—e.g. the first and second amplified signals—are supplied to an output circuit. This comprises in this embodiment a predetermined number of lumped element artificial lines. The number of artificial lines corresponds to the number of peak amplifiers. The output circuit serves to combine the first and second amplified signals so as to generate a single amplified output signal supplied to an output terminal. The output circuit is suitably implemented with wirebonds. Specific circuits are disclosed in WO-A 2006/003608.

To compensate for the low gain of the one or more peak amplifiers which may operate in C-class mode, i.e. at a negative input bias, non-equal power splitting is performed in the input circuit. Furthermore, to diminish the effect of variable input impedance of the peak amplifiers, hybrids are used in the input circuit to provide enhanced isolation between the ports of the input circuit.

The linearity versus efficiency characteristic of the Doherty type amplifier arrangement can be optimized by using a phase control at the input of the main and peak amplifiers and by using dynamic bias voltages to control the peak amplifiers. The required power distribution can be provided by establishing a non-equal power division at the input circuit.

In the embodiment of FIG. 2, the unit cell comprises the main amplifier (Main) and the Peak amplifier coupled to an input signal via a lumped element Lps. Each unit cell comprises at its input terminal a compensation circuit Lc for increasing an input impedance of the Main amplifier and Peak amplifier, respectively. FET or LDMOST power devices provides a relatively low input impedance, which in turn determines a limitation for their operational bandwidth. For example, a 10 W LDMOST power transistor has real part of input impedance around 0.25 ohm. FET power devices are voltage controlled devices meaning that depends on a voltage amplitude on their gate-source capacitance (Cgs). Best input matching for power FETs, which provides a relatively high impedance is achieved using a parallel inductance Lc for providing a parallel-type of resonance at the operating frequency. A voltage across the gate-source capacitor Cgs may be further controlled by an additional capacitor Cd which influence the resonant frequency of the circuit Lc, Cgs, Cd.

FIG. 3 depicts a model of the unit cell according to an embodiment of the invention. In FIG. 2, a capacitor between an end of the compensation inductor Lc and a reference terminal decuples said end and, as a consequence, the gate of the transistor from the reference terminal. Therefore, in the model presented in FIG. 3, said capacitors arew not figured.

The main amplifier and the peak amplifier each may comprise a power device in bipolar technology, MOS (Metal Oxide Semiconductor) technology, LDMOST (Lateral Defused Metal Oxide Semiconductor Transistor) technology, FET (Field Effect Transistor) technology, or HBT (Heterojunction Bipolar Transistor) technology. Different substrate technologies such as Si, GaAs, GaN, InP, SiC, SiGe may be used. The LDMOST technology provides high gain and good linearity compared to the other semiconductor technologies. However, complex modulation schemes, like WCDMA, make further device improvements for linearity still very desirable. Therefore, the suggested Doherty type amplifier arrangement enhances the performance of the LDMOST technology or other RF power devices technologies mentioned above. For example, HBT MMIC power devices may be used, where the heterojunction increases breakdown voltage and minimizes leakage current between junctions.

FIG. 4 shows a design example of a unit cell of the present invention and FIG. 5 shows an example in a bird-eye's perspective. The functions of the individual parts will be clear on the basis of comparison with FIG. 2.

FIG. 6 shows a graph of the present invention. It was found that this Doherty delivers an operational frequency bandwidth for a Doherty amplifier arrangement that is by far broader than any Doherty known so far. It is believed that a Doherty amplifier cannot have a larger bandwidth than 100 MHz. However, it was found that the present amplifier, suitably optimized, can achieve a bandwidth of 400 MHz. This implies that one amplifier may cover the range of 1800-2200 MHz, and thus in other words both the PCS and WCDMA bands.

FIG. 7 shows another graph of the same Doherty amplifier. This graph shows that an efficiency improvement of 8-10% in comparison to earlier Doherty amplifiers has been achieved. The efficiency improvement in comparison to traditional AB-class amplifiers is 30-40% at comparable linearity.

In short, the present invention provides an improved Doherty type of amplifier arrangement using a distributed approach, in which in a single amplifier arrangement a plurality of unit cells are present. The unit cell has for instance 1 to 20 W power, suitably 5-12 W. Using a 10 W unit cell, a Doherty type of amplifier arrangement of any power in the range of 10 W to at least 180 W can be created just be putting Doherty unit cells in parallel in a single package. This approach has several advantages:

less problems during design due to low power of the unit cell, as the modelling is more adequate (modelling of high power amplifiers such as LDMOS is not straightforward)

more control over parasitic elements

modifications possible to obtain a power amplifier arrangement for a specific frequency band. This is important, as new frequency bands are emerging. One example is Wi-Max. This requires a frequency band in the range of 2.5-2.7 GHz and 3.5 GHz, which is clearly different from GSM and WCDMA.

better reliablity of the amplifier arrangement due to better heat spread and lower temperature of the chip

the preferred use of lumped elements for input and output circuits gives more freedom for harmonic terminations and better efficiency

a borader frequency band is enabled with such Doherty amplifier arrangement than with an AB-class device

a higher input and output impedance is enabled than a AB-class amplifier can provide. This is particularly important for professional applications, such as for instance basestations for mobile phones.

1. An integrated Doherty type amplifier arrangement comprising a plurality of unit cells that are connected in parallel, each unit cell comprising
a main amplifier stage having an input terminal for receiving a first signal and for amplifying the first signal to generate a first amplified signal;
at least one peak amplifier stage having an input terminal for receiving at least one respective second signal, said peak amplifier stage being arranged to start operation when the level of that respective second signal has reached a predetermined threshold to generate at least one second amplified signal;
an input circuit for splitting an input signal of said amplifier arrangement into said first and at least one second signal at a predetermined phase shift; and
an output circuit in which the first amplified signal is combined with any second amplified signal as far as present to generate an output signal.

2. The amplifier arrangement as claimed in claim 1, wherein the main amplifier stage comprises at its input terminal a compensation circuit for increasing an input impedance.

3. The amplifier arrangement as claimed in claim 1, wherein the at least one peak amplifier stage comprises a compensation circuit for increasing an input impedance at its input terminal.

4. The amplifier arrangement as claimed in claim 3, wherein the compensation circuit comprises an inductor.

5. The amplifier arrangement as claimed in claim 4, wherein the compensation circuit further comprises a capacitor and is coupled to ground.

6. The amplifier arrangement as claimed in claim 5, further comprising a carrier with a metallisation wherein which metallisation the compensation conductors are defined.

7. The amplifier arrangement as claimed in claim 1, wherein the output circuit comprises at least one lumped element artificial line for receiving said first amplified signal and for applying said predetermined phase shift to said first amplified signal.

8. The amplifier arrangement as claimed in claim 1, wherein a single unit cell has a power output in the range of 1 to 20 W.

9. The amplifier arrangement as claimed in claim 1, wherein at least three unit cells are connected in parallel, and the peak and the main amplifier stages of those unit cells are present on a single chip.

10. The amplifier arrangement as claimed in claim 1, wherein the input circuit comprises an input capacitor coupled between the compensation circuit and the main amplifier stage, which input capacitor is coupled to the first amplifier stage and to an input of the unit cell with one or more wirebonds.

11. The amplifier arrangement as claimed in claim 1, wherein an input of the arrangement is defined with a single input pad.

12. The amplifier arrangement as claimed in claim 11, wherein the output of the arrangement is defined with a single output pad.

13. (canceled)
